(19) United States
(12) Patent Application Publication
(10) Pub. No.: US 2025/0051604 A1
(43) Pub. Date: Feb. 13, 2025

(54) HARDMASK COMPOSITION, HARDMASK LAYER AND METHOD OF FORMING PATTERNS

(71) Applicant: SAMSUNG SDI CO., LTD., Yongin-si (KR)

(72) Inventors: Sunghwan KIM, Suwon-si (KR); Sanghee PARK, Suwon-si (KR); Hyejeong KIM, Suwon-si (KR); Seil CHOI, Suwon-si (KR); Soohee KIM, Suwon-si (KR)

(21) Appl. No.: 18/428,227

(22) Filed: Jan. 31, 2024

(30) Foreign Application Priority Data
Aug. 7, 2023 (KR) 10-2023-0103085

(51) Int. Cl. C09D 165/00; C08G 61/12; G03F 7/16; H01L 21/027

(52) U.S. Cl. CPC C09D 165/00; C08G 61/12; G03F 7/168; H01L 21/0274; C08G 2261/124; C08G 2261/1412; C08G 2261/1422; C08G 2261/148; C08G 2261/228; C08G 2261/312; C08G 2261/314; C08G 2261/334

(57) ABSTRACT

A hardmask composition, a hardmask layer manufactured from the hardmask composition, and a method of forming patterns using the hardmask layer manufactured from the hardmask composition, the hardmask composition includes a polymer including a structural unit represented by the following Chemical Formula 1; and a solvent,

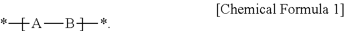

### CROSS-REFERENCE TO RELATED APPLICATION

This application claims priority to and the benefit of Korean Patent Application No. 10-2023-0103085 filed in the Korean Intellectual Property Office on Aug. 7, 2023, the entire contents of which are incorporated herein by reference.

### BACKGROUND

### 1. Field

Embodiments relate to a hardmask composition, a hardmask layer, and a method of forming patterns.

### 2. Description of the Related Art

Recently, the semiconductor industry has developed to an ultra-fine technique having a pattern of several to several tens nanometer size. Such ultrafine technique may utilize effective lithographic techniques.

Some lithographic techniques may include providing a material layer on a semiconductor substrate; coating a photoresist layer thereon; exposing and developing the same to provide a photoresist pattern; and etching a material layer using the photoresist pattern as a mask.

According to small-sizing the pattern to be formed, it may be difficult to provide a fine pattern having an excellent profile by only using some lithographic techniques. Accordingly, an auxiliary layer, called a hardmask layer, may be formed between the material layer and the photoresist layer to provide a fine pattern.

### SUMMARY

The embodiments may be realized by providing CLAIM LANGUAGE TO BE ADDED
a hardmask composition including a polymer including a structural unit represented by Chemical Formula 1; and a solvent:

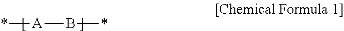

wherein, in Chemical Formula 1, A is a substituted or unsubstituted aromatic group, a substituted or unsubstituted heteroaromatic group, a group in which two or more substituted or unsubstituted aromatic groups or substituted or unsubstituted heteroaromatic groups are linked by a single bond or —CR^{x}R^{y}—, in which R^{x} and R^{y} are each independently a substituted or unsubstituted aromatic group or a substituted or unsubstituted heteroaromatic group, R^{x} and R^{y} being separate or linked to form a fused ring, or a combination thereof, B is a group represented by Chemical Formula 2, and * is a linking point:

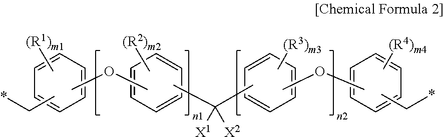

wherein, in Chemical Formula 2, X¹ and X² are each independently a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C1 to C20 saturated or unsaturated heteroaliphatic hydrocarbon group, a substituted or unsubstituted C2 to C20 saturated or unsaturated heteroalicyclic hydrocarbon group, a substituted or unsubstituted C6 to C30 aromatic group, a substituted or unsubstituted C6 to C30 heteroaromatic group, or a combination thereof, X¹ and X² being separate or being linked to each other to form a substituted or unsubstituted C3 to C30 hydrocarbon ring group, R¹ to R⁴ are each independently deuterium, a hydroxy group, a halogen atom, —NR^{a}R^{b}, in which R^{a} and R^{b} are each independently hydrogen or a substituted or unsubstituted C1 to C10 alkyl group, a substituted or unsubstituted C1 to C20 alkoxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C3 to C20 cycloalkenyl group, a substituted or unsubstituted C3 to C20 cycloalkynyl group, a substituted or unsubstituted C3 to C20 hetero cycloalkyl group, a substituted or unsubstituted C6 to C20 aryl group, a substituted or unsubstituted C6 to C20 heteroaryl group, or a combination thereof, m1 to m4 are each independently an integer of 0 to 4, and n1 and n2 are each independently an integer of 1 to 4.

A may be a substituted or unsubstituted C6 to C20 aromatic group, a moiety in which two or more substituted or unsubstituted C6 to C20 aromatic rings are linked by a single bond or —CR^{x}R^{y}—, in which R^{x} and R^{y} are each independently a substituted or unsubstituted C6 to C10 aromatic ring, R^{x} and R^{y} being separate or linked to form a fused ring, or a combination thereof.

A may be a substituted or unsubstituted group of a moiety of Group 1 or a moiety of Group 2,

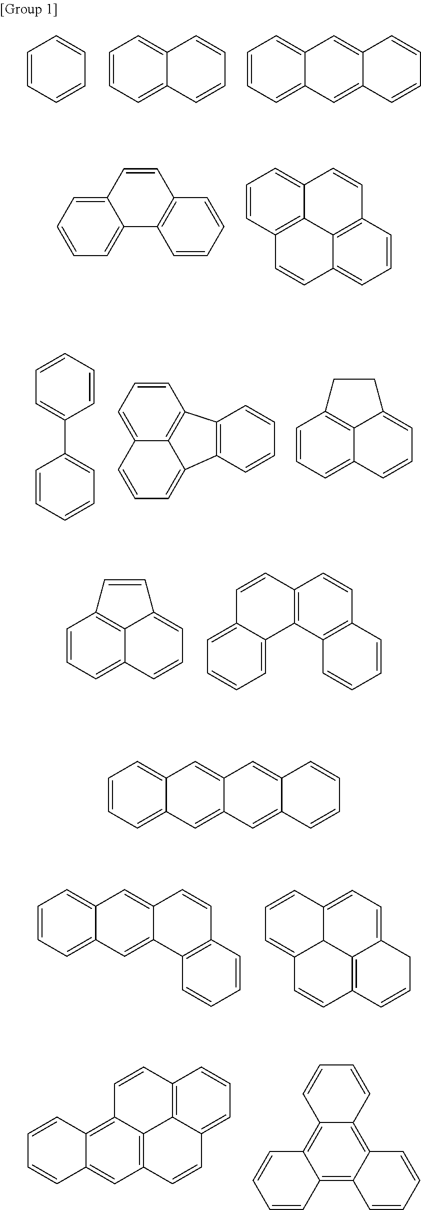

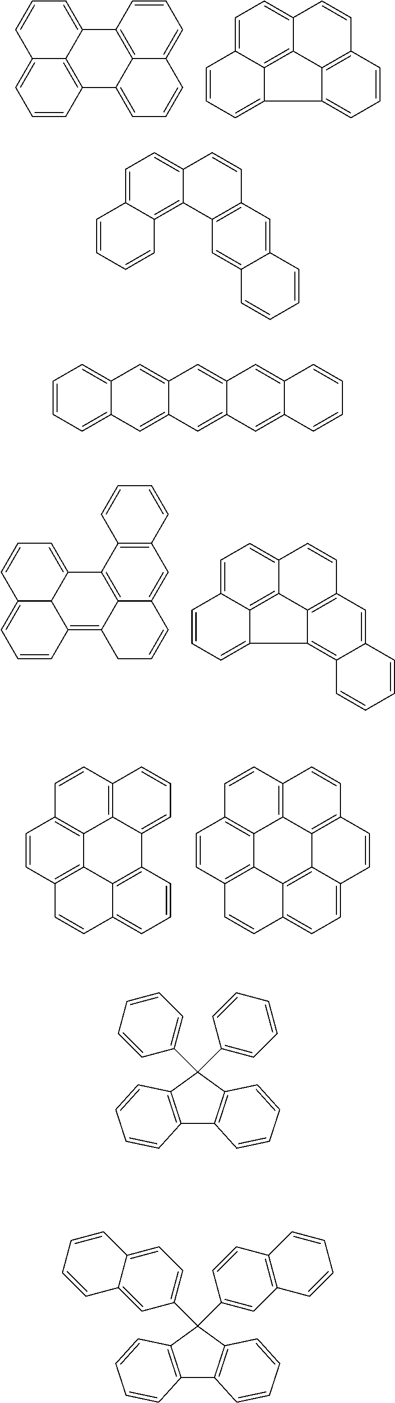

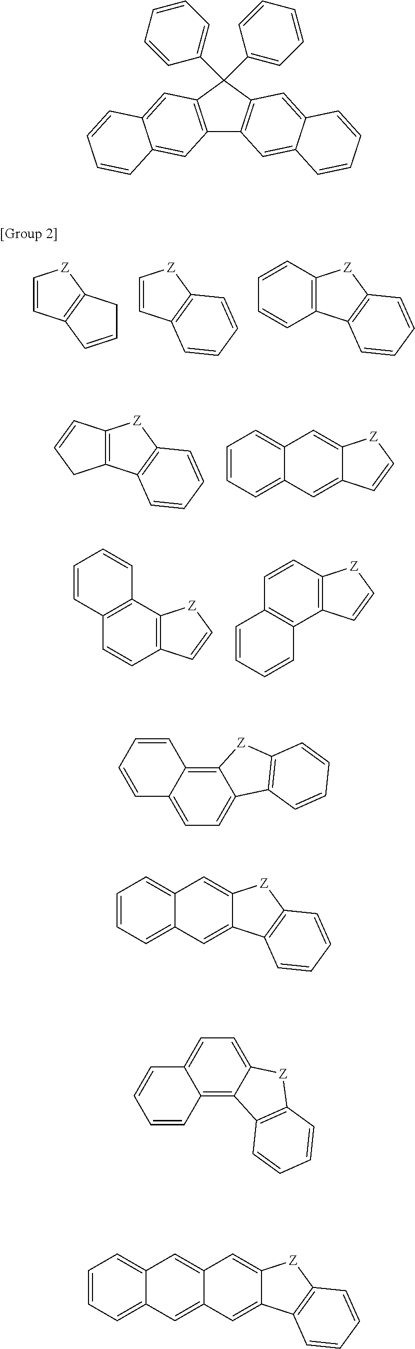

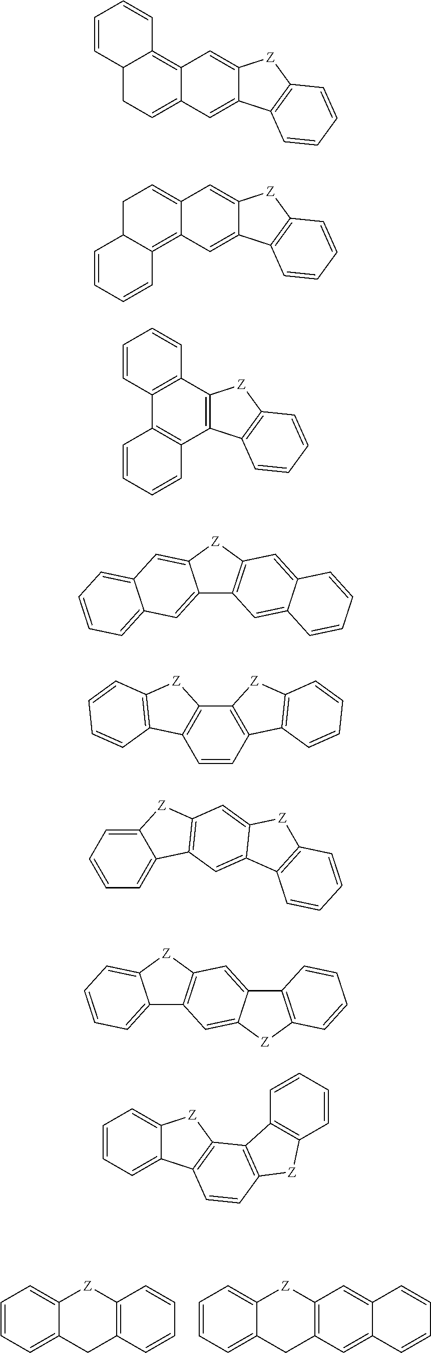

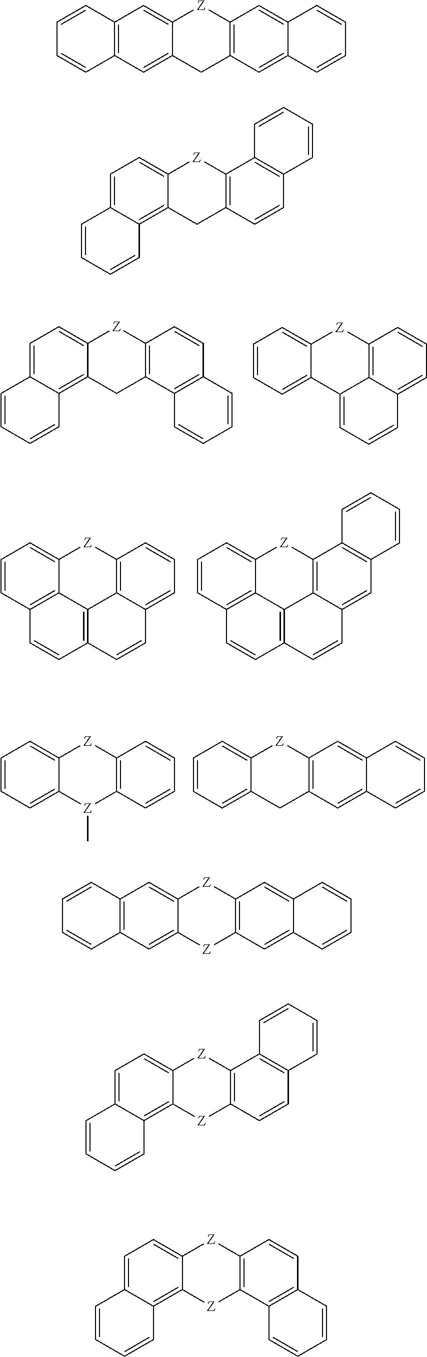

in Group 2, Z and Z′ may each independently be —O—, —S—, —P—, or —NR^{c}—, in which R^{c} is hydrogen, deuterium, or a substituted or unsubstituted C1 to C5 alkyl group.

In Chemical Formula 2, X¹ and X² may each independently be a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C30 aromatic ring group, or a combination thereof, and X¹ and X² may be linked to form a substituted or unsubstituted C3 to C20 hydrocarbon cyclic group.

In Chemical Formula 2, X¹ and X² may each independently be a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C20 aryl group, or a combination thereof, and X¹ and X² may be linked to form a substituted or unsubstituted C3 to C20 hydrocarbon cyclic group.

In Chemical Formula 2, R¹ to R⁴ may each independently be deuterium, a hydroxy group, a halogen atom, a substituted or unsubstituted C1 to C20 alkoxy group, a substituted or unsubstituted C1 to C10 alkyl group, a substituted or unsubstituted C6 to C20 aryl group, or a combination thereof, and m1 to m4 may each independently be an integer of 0 to 2.

In Chemical Formula 2, X¹ and X² may each independently be a substituted or unsubstituted C1 to C20 alkyl group, a substituted or unsubstituted C6 to C20 aryl group, wherein X¹ and X² are linked to form a substituted or unsubstituted C3 to C20 hydrocarbon cyclic group, or a combination thereof, m1 to m4 may each be 0, and n1 and n2 may each independently be 1 or 2.

Chemical Formula 2 may be represented by one of Chemical Formula 2-1 to Chemical Formula 2-5:

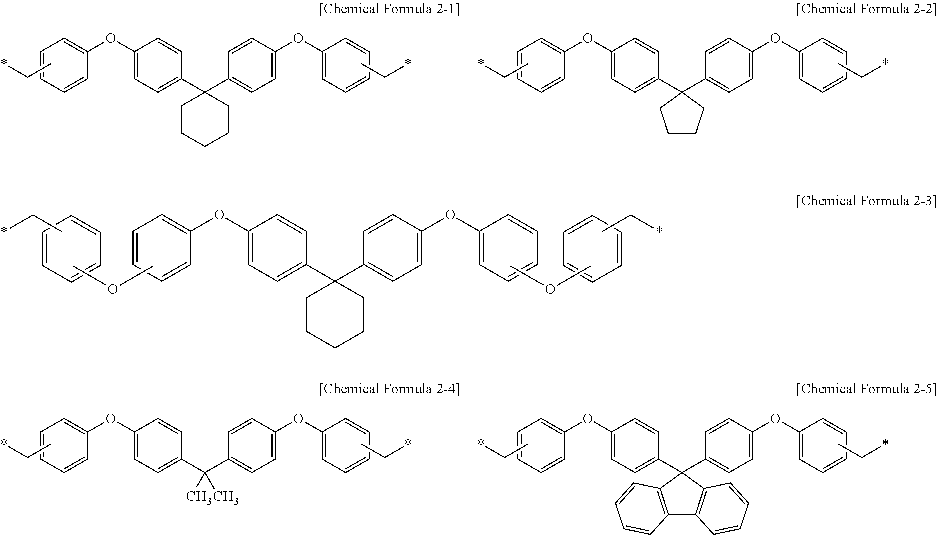

in Chemical Formula 2-1 to Chemical Formula 2-5, * is a linking point.

Chemical Formula 1 may be represented by one of Chemical Formula 1-1 to Chemical Formula 1-7,

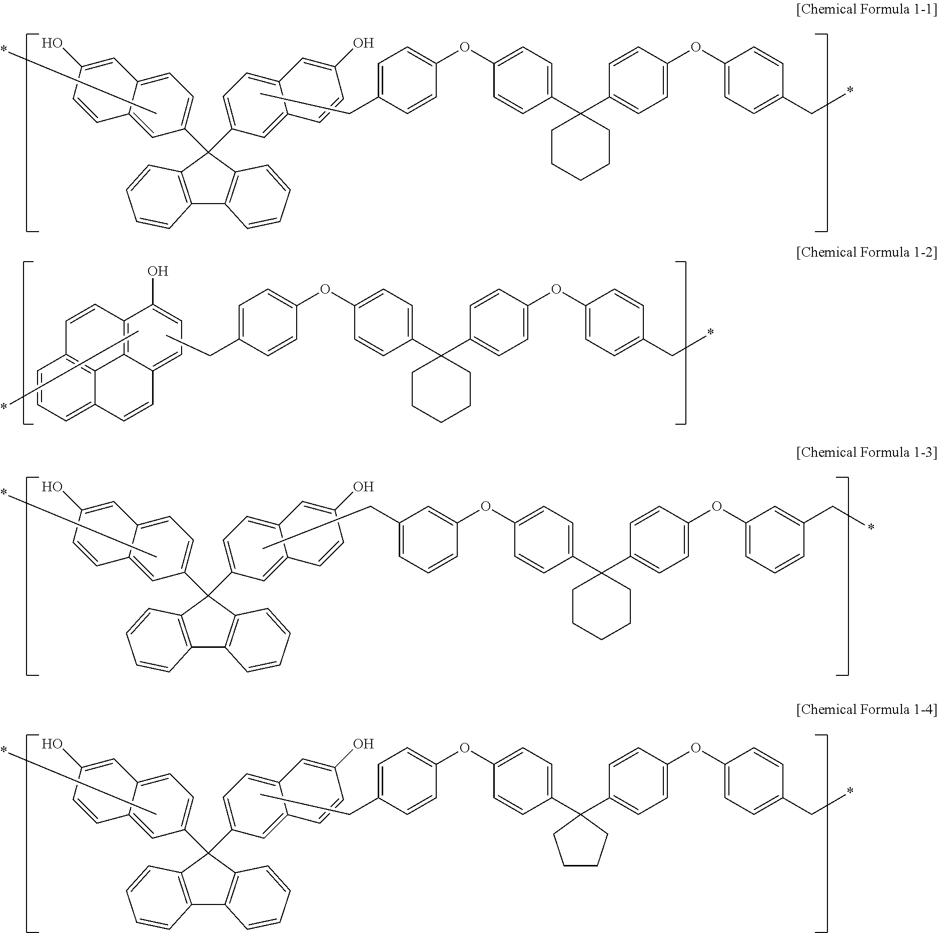

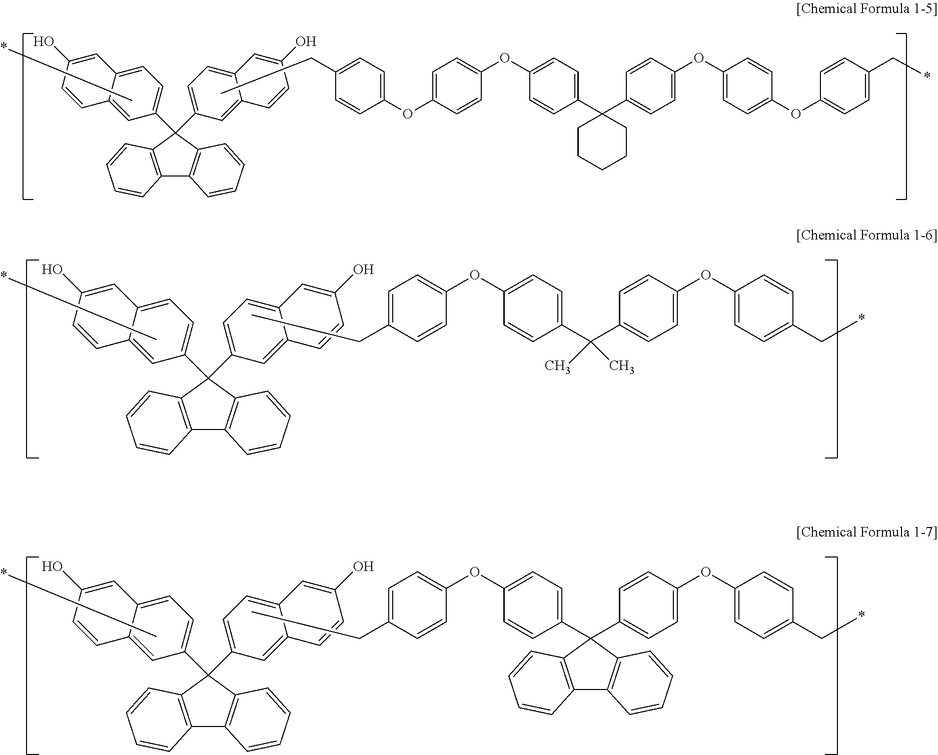

in Chemical Formula 1-1 to Chemical Formula 1-7, * is a linking point.

The polymer may have a weight average molecular weight of about 1,000 g/mol to about 200,000 g/mol.

The polymer may be included in an amount of about 0.1 wt % to about 30 wt %, based on a total weight of the hardmask composition.

The solvent may include propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

The embodiments may be realized by providing a hardmask layer comprising a cured product of the hardmask composition according to an embodiment.

The embodiments may be realized by providing a method of forming patterns, the method including providing a material layer on a substrate; applying the hardmask composition according to an embodiment to the material layer; heat-treating the hardmask composition to form a hardmask layer; forming a photoresist layer on the hardmask layer; exposing and developing the photoresist layer to form a photoresist pattern; selectively removing the hardmask layer using the photoresist pattern to expose a portion of the material layer; and etching an exposed part of the material layer.

Forming the hardmask layer may include heat-treating at about 100° C. to about 1,000° C.

### BRIEF DESCRIPTION OF THE DRAWING

Features will be apparent to those of skill in the art by describing in detail exemplary embodiments with reference to the attached drawing in which:

the FIGURE is a reference diagram illustrating a level difference of a hardmask layer to explain a method of evaluating planarization characteristics.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present.

As used herein, when a definition is not otherwise provided, ‘substituted’ may refer to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C9 to C30 allylaryl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof. As used herein, hydrogen substitution (—H) may include deuterium substitution (-D) or tritium substitution (-T). For example, any hydrogen in any compound described herein may be protium, deuterium, or tritium (e.g., based on natural or artificial substitution). As used herein, the term “or” is not necessarily an exclusive term, e.g., “A or B” would include A, B, or A and B.

In addition, adjacent two substituents of the substituted halogen atom (F, Br, Cl, or I), the hydroxy group, the nitro group, the cyano group, the amino group, the azido group, the amidino group, the hydrazino group, the hydrazono group, the carbonyl group, the carbamyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, the C2 to C30 heterocyclic group may be fused to form a ring.

As used herein, when a definition is not otherwise provided, “aromatic hydrocarbon” refers to a group having one or more hydrocarbon aromatic moieties, including a form in which hydrocarbon aromatic moieties are linked by a single bond, a non-aromatic fused ring form in which hydrocarbon aromatic moieties are fused directly or indirectly, or a combination thereof as well as non-fused aromatic hydrocarbon rings, fused aromatic hydrocarbon rings.

More specifically, the substituted or unsubstituted aromatic hydrocarbon may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a combination thereof, or a combined fused ring of the foregoing groups, but is not limited thereto.

As used herein, when a definition is not otherwise provided, “hetero” means containing one or more hetero atoms selected from N, O, S, Se, and P.

As used herein, when a definition is not otherwise provided, a “heteroaromatic” means containing at least one atom selected from N, O, S, Se, and P in aromatic hydrocarbon rings.

More specifically, the substituted or unsubstituted heteroaromatic group may be a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridinyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzthiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted fluorenyl group, a substituted or unsubstituted dibenzofuranyl group, a substituted or unsubstituted dibenzothiphenyl group, a substituted or unsubstituted carbazolyl group, a pyridoindolyl group, a benzopyridooxazinyl group, a benzopyridothiazinyl group, a 9,9-dimethyl-9,10-dihydroacridinyl group, a combination thereof, or a combined fused ring of the foregoing groups, but is not limited thereto.

As used herein, when specific definition is not otherwise provided, the term “combination” refers to mixing or copolymerization.

As used herein, the “polymer” may include both an oligomer and a polymer.

Unless otherwise specified in the present specification, the “weight average molecular weight” is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

The hardmask composition according to some embodiments may include, e.g., a polymer including a structural unit represented by Chemical Formula 1, and a solvent.

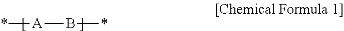

In Chemical Formula 1, A may be or may include, e.g., a substituted or unsubstituted aromatic group, a substituted or unsubstituted heteroaromatic group, a group in which two or more substituted or unsubstituted aromatic groups or heteroaromatic groups are linked by a single bond or —CR^{x}R^{y}—, or a combination thereof. R^{x} and R^{y} may each independently be, e.g., a substituted or unsubstituted aromatic group or a substituted or unsubstituted heteroaromatic group. In an implementation, the substituted or unsubstituted aromatic group or substituted or unsubstituted heteroaromatic group of R^{x} and R^{y} may be separate or may be linked to from a fused ring.

B may be, e.g., a group represented by Chemical Formula 2.

* is a linking point:

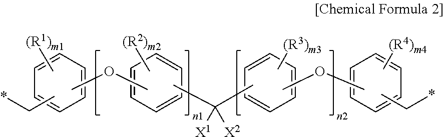

In Chemical Formula 2, X¹ and X² may each independently be or include, e.g., a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C1 to C20 saturated or unsaturated heteroaliphatic hydrocarbon group, a substituted or unsubstituted C2 to C20 saturated or unsaturated heteroalicyclic hydrocarbon group, a substituted or unsubstituted C6 to C30 aromatic ring group, a substituted or unsubstituted C6 to C30 heteroaromatic ring group, or a combination thereof. In an implementation, X¹ and X² may be separate or may be linked to each other to form a substituted or unsubstituted C3 to C30 hydrocarbon ring group.

R¹ to R⁴ may each independently be or include, e.g., deuterium, a hydroxy group, a halogen atom, —NR^{a}R^{b}, in which R^{a} and R^{b} may each independently be hydrogen or a substituted or unsubstituted C1 to C10 alkyl group, a substituted or unsubstituted C1 to C20 alkoxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C3 to C20 cycloalkenyl group, a substituted or unsubstituted C3 to C20 cycloalkynyl group, a substituted or unsubstituted C3 to C20 hetero cycloalkyl group, a substituted or unsubstituted C6 to C20 aryl group, a substituted or unsubstituted C6 to C20 heteroaryl group, or a combination thereof.

m1 to m4 may each independently be, e.g., an integer of 0 to 4.

n1 and n2 may each independently be, e.g., an integer of 1 to 4.

In an implementation, the composition may include a polymer including a substituted or unsubstituted aromatic group, a substituted or unsubstituted heteroaromatic group, or a linked moiety of these in the structural unit thereof, thereby increasing the carbon content in the polymer and securing etch resistance. In an implementation, the group represented by Chemical Formula 2 may be included, and flexibility within the polymer may be increased. The flexible structure may help increase a free volume of the polymer, which may not only help improve a solubility of the polymer in solvents but may also lower a glass transition temperature (Tg) of the composition. In an implementation, reflow during baking of the composition may increase, thereby improving the gap-fill characteristics and planarization characteristics of the hardmask layer formed therefrom.

In an implementation, A may be, e.g., a substituted or unsubstituted C6 to C20 aromatic group, a group in which two or more substituted or unsubstituted C6 to C20 aromatic groups are linked by a single bond or —CR^{x}R^{y}—, in which R^{x} and R^{y} may each independently be a substituted or unsubstituted C6 to C10 aromatic ring wherein these aromatic rings may be linked to form a fused ring, or a combination thereof. In an implementation, A may be, e.g., a substituted or unsubstituted group of a moiety of Group 1 or a moiety of Group 2. In an implementation, A may be, e.g., a substituted or unsubstituted group of a moiety of Group 1.

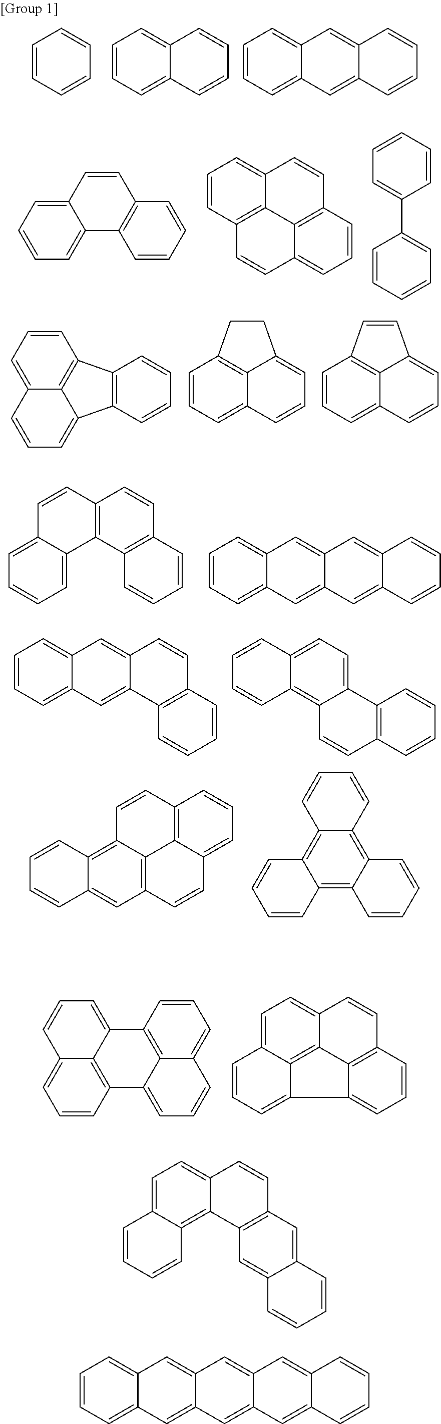

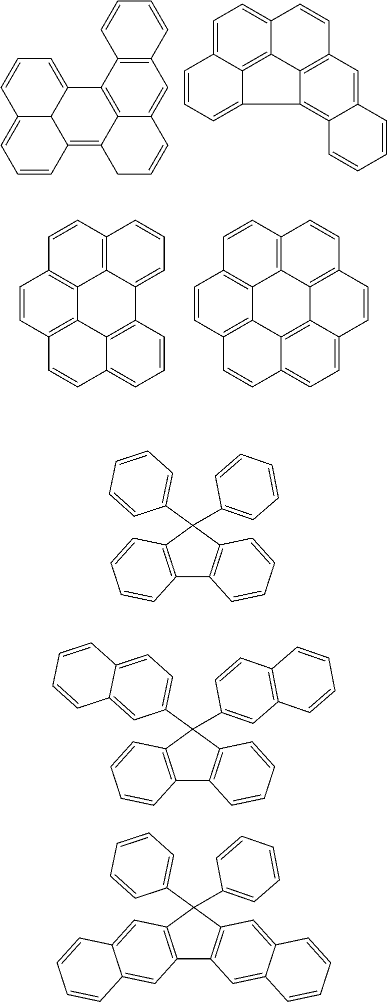

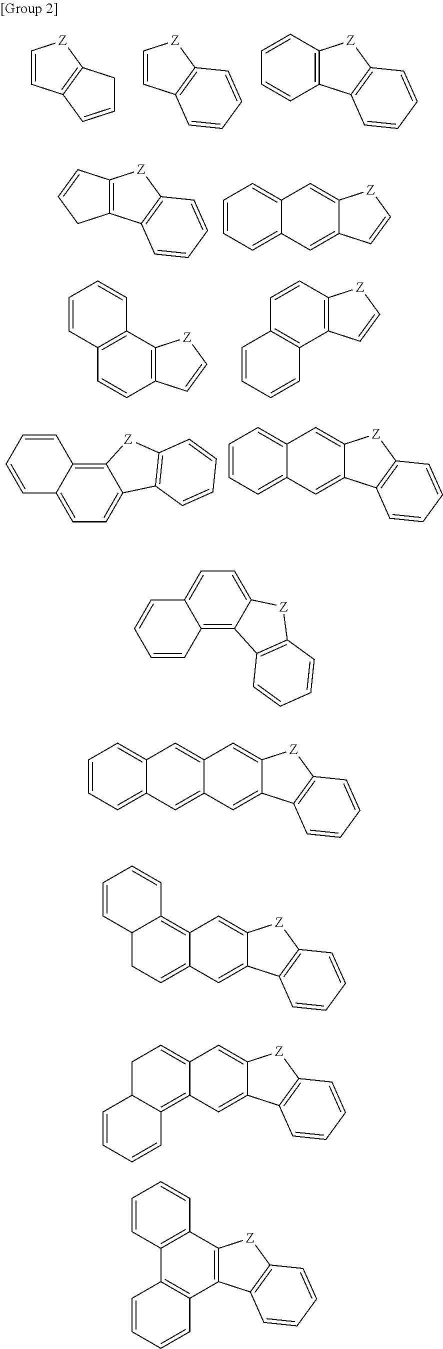

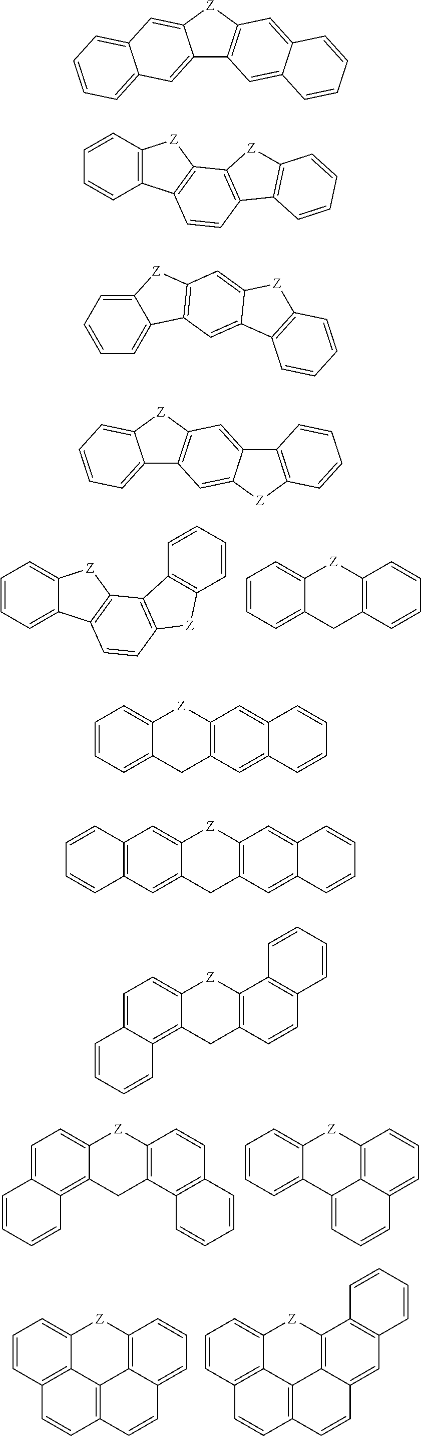

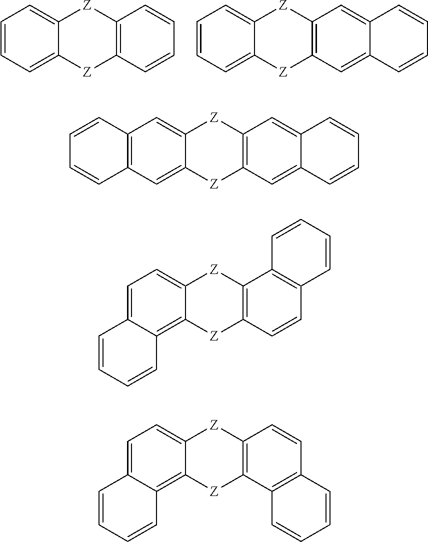

In Group 2, Z and Z′ may each independently be, e.g., —O—, —S—, —P—, or —NR^{c}—, in which R^{c} may be, e.g., hydrogen, deuterium, or a substituted or unsubstituted C1 to C5 alkyl group.

In an implementation, A may be or may include, e.g., benzene, naphthalene, anthracene, phenanthrene, pyrene, fluorene derivative, indole, carbazole, or benzocarbazole, which may be substituted or unsubstituted.

In an implementation, in Chemical Formula 2, X¹ and X² may each independently be, e.g., a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C30 aromatic ring group, or a combination thereof. In an implementation, X¹ and X² may be linked to form a substituted or unsubstituted C3 to C20 hydrocarbon cyclic or ring group. In an implementation, X¹ and X² may each independently be, e.g., a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C20 aryl group, or a combination thereof. In an implementation, X¹ and X² may be linked to form a substituted or unsubstituted C3 to C20 hydrocarbon cyclic or ring group.

In the substituted or unsubstituted C3 to C20 hydrocarbon ring group formed by linking X¹ and X², a cycloalkyl group, a cycloalkenyl group, a cycloalkynyl group, or an aromatic ring may exist singly, or two or more hydrocarbon rings may be fused. In an implementation, X¹ and X² may be alkyl groups, and they may be linked to form cyclopentane, cyclohexane, or the like. In an implementation, X¹ and X² may be aryl groups, e.g., each may be a phenyl group, and the two carbon atoms present in the ortho position of the carbon atom of the phenyl group may be linked to the quaternary carbon to which X¹ and X² are linked by a single bond to form fluorene, and the hydrocarbon ring groups may be substituted or unsubstituted.

In an implementation, X¹ and X² may exist independently or separately, or X¹ and X² may be linked and exist as one moiety or group. In an implementation, by appropriately adjusting the structures of X¹ and X² to adjust the flexibility of the structural unit represented by Chemical Formula 2, the solubility of the polymer including it in the solvent may be adjusted.

In an implementation, in Chemical Formula 2, R¹ to R⁴ may each independently be, e.g., deuterium, a hydroxy group, a halogen atom, a substituted or unsubstituted C1 to C20 alkoxy group, a substituted or unsubstituted C1 to C10 alkyl group, a substituted or unsubstituted C6 to C20 aryl group, or a combination thereof, for example a hydroxy group, a substituted or unsubstituted C1 to C10 alkoxy group, a substituted or unsubstituted C1 to C10 alkyl group, or a combination thereof. In an implementation, in Chemical Formula 2, R¹ to R⁴ may each independently be, e.g., a hydroxy group.

In an implementation, in Chemical Formula 2, m1 to m4 may each independently be, e.g., an integer of 0 to 4, 0 to 2, 0 or 1, or 0.

In an implementation, in Chemical Formula 2, n1 and n2 may each independently be, e.g., an integer of 1 to 4, 1 to 3, or 1 or 2. By adjusting n1 and n2, the flexibility within the structural unit can be adjusted and the solubility of the polymer including it in a solvent may be adjusted.

In an implementation, Chemical Formula 2 may be represented by, e.g., one of Chemical Formula 2-1 to Chemical Formula 2-5.

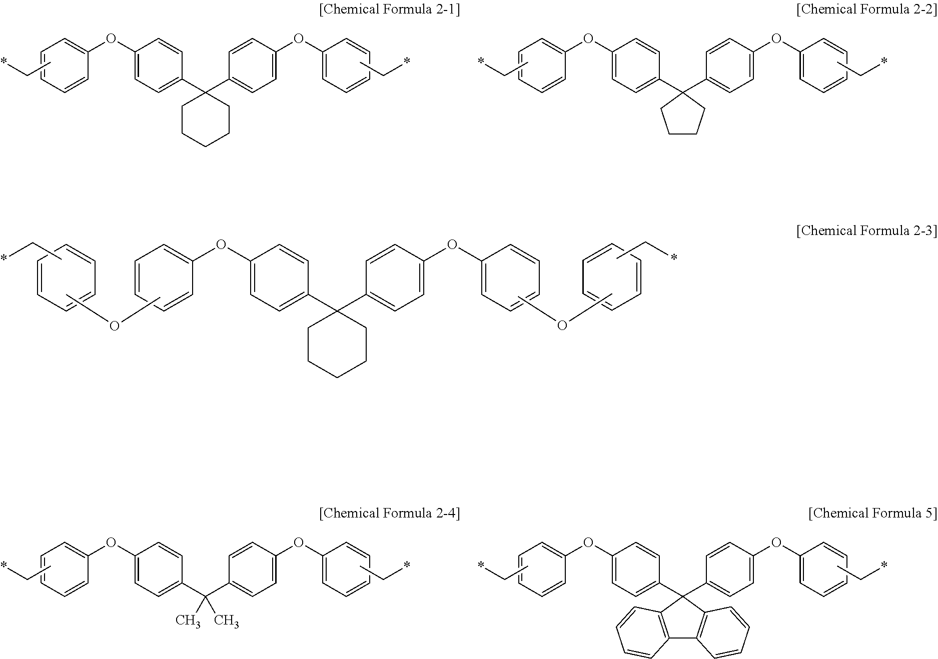

In Chemical Formula 2-1 to Chemical Formula 2-5, * is a linking point.

In an implementation, Chemical Formula 1 may be represented by, e.g., one of Chemical Formula 1-1 to Chemical Formula 1-7.

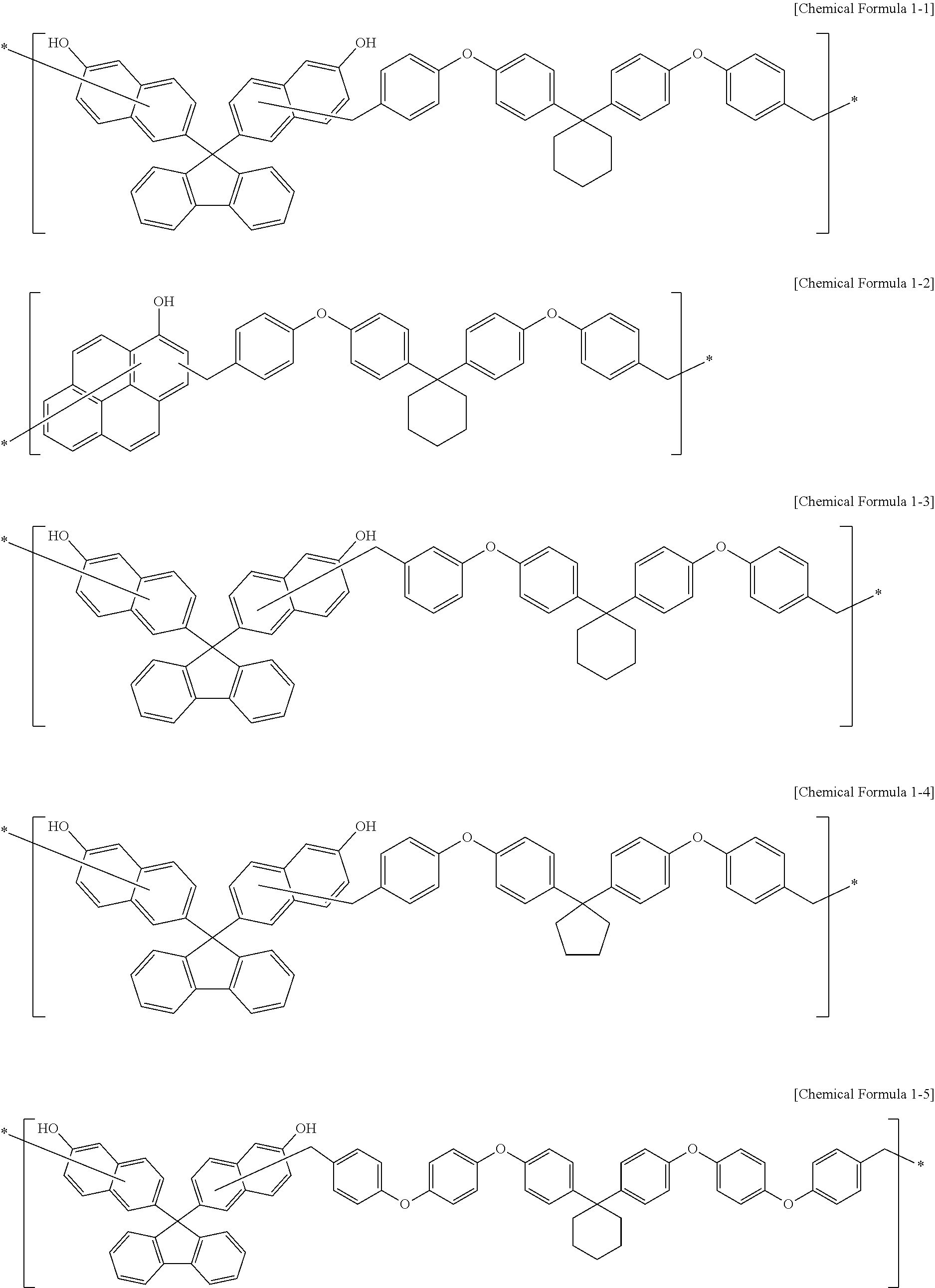

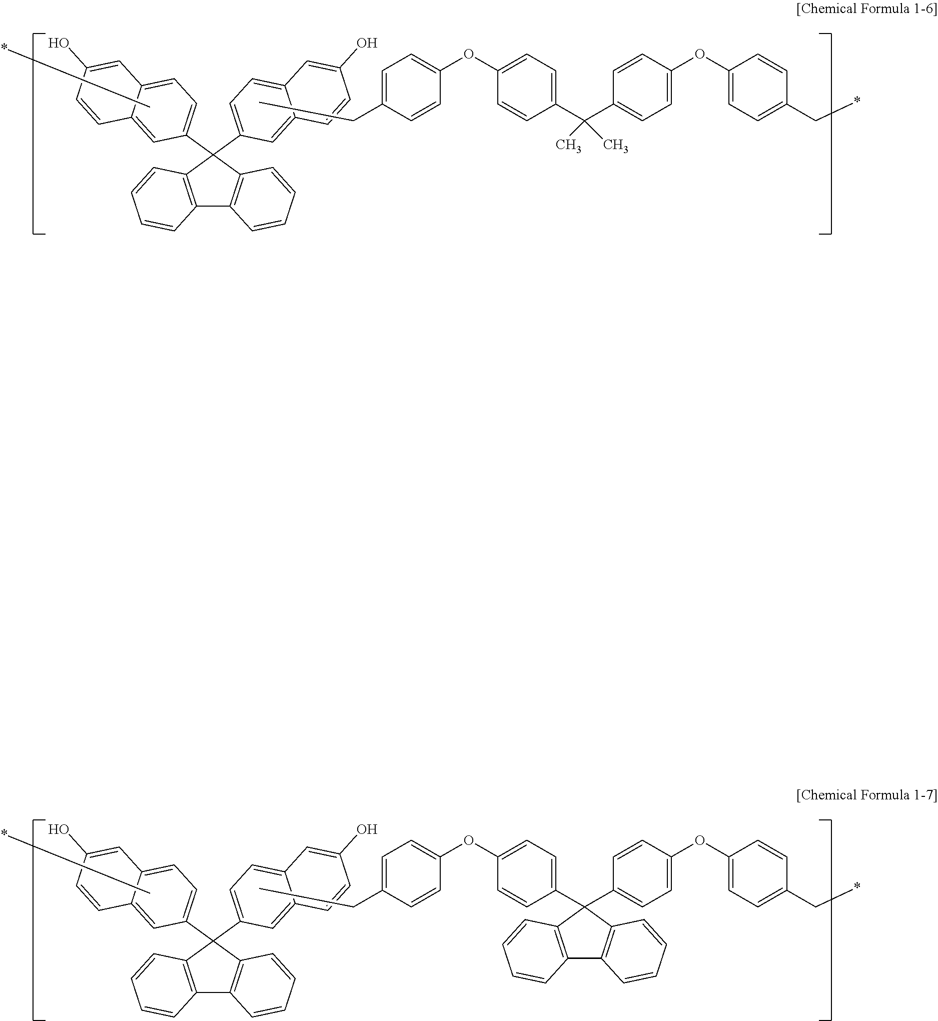

In Chemical Formula 1-1 to Chemical Formula 1-7, * is a linking point.

The polymer may have a weight average molecular weight of, e.g., about 1,000 g/mol to about 200,000 g/mol. In an implementation, the polymer may have a weight average molecular weight of, e.g., about 1,000 g/mol to about 150,000 g/mol, about 1,000 g/mol to about 100,000 g/mol, about 1,200 g/mol to about 50,000 g/mol, or about 1,200 g/mol to about 10,000 g/mol. By having a weight average molecular weight within the above ranges, the carbon content and solubility in the solvent of the hardmask composition including the above polymer may be adjusted and optimized.

The polymer may be included in an amount of, e.g., about 0.1 wt % to about 30 wt %, based on a total weight of the hardmask composition. In an implementation, the polymer may be included in an amount of, e.g., about 0.2 wt % to about 30 wt %, about 0.5 wt % to about 30 wt %, about 1 wt % to about 30 wt %, about 1.5 wt % to about 25 wt %, or about 2 wt % to about 20 wt %. By including the polymer within the above ranges, a thickness, a surface roughness, and a planarization degree of the hardmask may be easily adjusted.

The hardmask composition may include a solvent. In an implementation, the solvent may include, e.g., propylene glycol, propylene glycol diacetate, methoxy propanediol, diethylene glycol, diethylene glycol butyl ether, tri(ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, methylpyrrolidone, methylpyrrolidinone, acetylacetone, ethyl 3-ethoxypropionate, or the like. In an implementation, the solvent may include a suitable solvent that has sufficient solubility or dispersibility for the polymer.

The hardmask composition may further include an additive, e.g., a surfactant, a crosslinking agent, a thermal acid generator, or a plasticizer.

The surfactant may include, e.g., a fluoroalkyl compound, alkylbenzenesulfonate, alkylpyridinium salt, polyethylene glycol, a quaternary ammonium salt, or the like.

The crosslinking agent may include, e.g., a melamine, a substituted urea, or a polymer crosslinking agent. In an implementation, it may be a crosslinking agent having at least two crosslinking substituents, e.g., methoxymethylated glycoruryl, butoxymethylated glycoruryl, methoxymethylated melamine, butoxymethylated melamine, methoxymethylated benzoguanamine, butoxy methylated benzoguanamine, methoxymethylated urea, butoxymethylated urea, methoxymethylated thiourea, or butoxymethylated thiourea.

In an implementation, as the crosslinking agent, a crosslinking agent having high heat resistance may be used. The crosslinking agent having high heat resistance may include a compound containing a crosslinking substituent having an aromatic ring (e.g., a benzene ring or a naphthalene ring) in the molecule.

The thermal acid generator may include, e.g., an acid compound, such as p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid, or 2,4,4,6-tetrabromocyclohexadienone, benzointosylate, 2-nitrobenzyltosylate, or other organic sulfonic acid alkyl esters.

According to some embodiments, a hardmask layer including a cured product of the aforementioned hardmask composition may be provided.

Hereinafter, a method of forming patterns using the aforementioned hardmask composition is described.

A method of forming patterns according to some embodiments may include providing a material layer on a substrate, applying a hardmask composition including the aforementioned polymer and solvent to the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a part of the material layer, and etching the exposed part of the material layer.

The substrate may be, e.g., a silicon wafer, a glass substrate, or a polymer substrate. The material layer is a material to be finally patterned, e.g., a metal layer such as an aluminum layer or a copper layer, a semiconductor layer such as a silicon layer, or an insulation layer such as a silicon oxide layer or a silicon nitride layer. The material layer may be formed through a method such as a chemical vapor deposition (CVD) process.

The hardmask composition may be the same as described above, and may be applied by spin-on coating in a form of a solution. In an implementation, an application thickness of the hardmask composition may be, e.g., about 50 Å to about 200,000 Å.

The heat-treating of the hardmask composition may be performed, e.g., at about 100° C. to about 1,000° C. for about 10 seconds to about 1 hour. In an implementation, the heat-treating of the hardmask composition may include a plurality of heat-treating processes, e.g., a first heat-treating process, and a second heat-treating process.

In an implementation, the heat-treating of the hardmask composition may include, e.g., one heat-treating process performed at about 100° C. to about 1,000° C. for about 10 seconds to about 1 hour. In an implementation, the heat-treating may be performed under an atmosphere of air or nitrogen, or an atmosphere having oxygen concentration of 1 wt % or less.

In an implementation, the heat-treating of the hardmask composition may include, e.g., a first heat-treating process performed at about 100° C. to about 1,000° C., about 100° C. to about 800° C., about 100° C. to about 500° C., or about 150° C. to about 400° C. for, e.g., about 30 seconds to about 1 hour, about 30 seconds to about 30 minutes, about 30 seconds to about 10 minutes, or about 30 seconds to about 5 minutes.

In an implementation, the heat-treating of the hardmask composition may include, e.g., a second heat-treating process performed at about 100° C. to 1,000° C., about 300° C. to about 1,000° C., about 500° C. to about 1,000° C., about 500° C. to about 600° C. for, e.g., about 30 seconds to about 1 hour, about 30 seconds to about 30 minutes, about 30 seconds to about 10 minutes, or about 30 seconds to about 5 minutes, consecutively. In an implementation, the first and second heat-treating process may be performed under an air or nitrogen atmosphere, or may be performed in an atmosphere with an oxygen concentration of 1 wt % or less.

By performing at least one of the steps of heat-treating the hardmask composition at a high temperature of, e.g., 200° C. or higher, high etch resistance capable of withstanding etching gas and chemical liquid exposed in subsequent processes including the etching process may be exhibited.

In an implementation, the forming of the hardmask layer may include a UV/Vis curing process or a near IR curing process.

In an implementation, the forming of the hardmask layer may include a first heat-treating process, a second heat-treating process, a UV/Vis curing process, or a near IR curing process, or may include two or more processes consecutively.

In an implementation, the method may further include forming a silicon-containing thin layer on the hardmask layer. The silicon-containing thin layer may be formed of, e.g., SiCN, SiOC, SiON, SiOCN, SiC, SiO, SiN, or the like.

In an implementation, the method may further include forming a bottom antireflective coating (BARC) on the silicon-containing thin layer or on the hardmask layer before forming the photoresist layer.

In an implementation, exposure of the photoresist layer may be performed using, e.g., ArF, KrF, or EUV. After exposure, heat-treating may be performed at about 100° C. to about 700° C.

In an implementation, the etching process of the exposed part of the material layer may be performed through a dry etching process using an etching gas and the etching gas may be, e.g., N₂/O₂, CHF₃, CF₄, Cl₂, BCl₃, or a mixed gas thereof.

The etched material layer may be formed in a plurality of patterns, and the plurality of patterns may include a metal pattern, a semiconductor pattern, an insulation pattern, or the like, e.g., diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis of Compounds

### Synthesis Example 1

1,1-bis(4-hydroxyphenyl)cyclohexane (80.5 g, 0.3 mol), 4-fluorobenzaldehyde (74.5 g, 0.6 mol), potassium carbonate (82.9 g, 0.6 mol), and 400 mL of anhydrous N,N-dimethylformamide (DMF) were put in a flask and stirred 140° C. under nitrogen for 14 hours. When a reaction was completed, the reactant was cooled to ambient temperature and slowly added dropwise to cold water (1,000 mL). A solid produced therefrom was filtered and then, twice washed with 500 mL of water and a methanol aqueous solution (water:MeOH=5:1, 200 mL), and solvents remaining there were removed under a reduced pressure to obtain Compound 1a represented by Chemical Formula 1a.

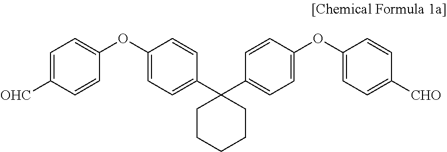 [SMILES: O=Cc1ccc(Oc2ccc(C3(c4ccc(Oc5ccc(C=O)cc5)cc4)CCCCC3)cc2)cc1]

Compound 1a (95.3 g, 0.2 mol) was dissolved in dichloromethane:MeOH (1:1, 500 mL), and sodium borohydride (22.7 g, 0.6 mol) was slowly added thereto at ambient temperature for 20 minutes and then, stirred at ambient temperature for 5 hours. When a reaction was completed, after removing about a half of the solvent under a reduced pressure, an organic layer was extracted therefrom by using 600 mL of ethyl acetate, and the remaining solvent was removed to obtain Compound 1b represented by Chemical Formula 1b.

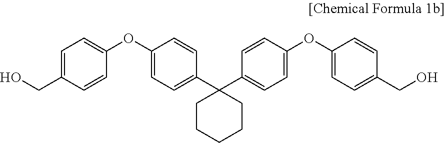 [SMILES: OCc1ccc(Oc2ccc(C3(c4ccc(Oc5ccc(CO)cc5)cc4)CCCCC3)cc2)cc1]

Compound 1b (48.0 g, 0.1 mol) was dissolved in 150 mL of anhydrous DMF, and sodium hydride (7.2 g, 0.3 mol) was slowly added thereto, while blowing nitrogen, and then, additionally stirred at ambient temperature for 30 minutes. Subsequently, iodomethane (71.0 g, 0.5 mol) was slowly added to the reactant in a dropwise fashion and then, additionally stirred at ambient temperature for 3 hours.

When a reaction was completed, an organic layer was extracted therefrom by using 500 mL of ethyl acetate and the remaining solvent was removed under a reduced pressure to obtain Compound 1 represented by Chemical Formula A through column chromatography.

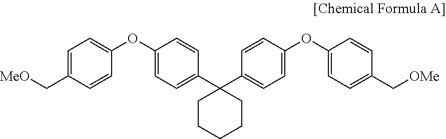 [SMILES: COCc1ccc(Oc2ccc(C3(c4ccc(Oc5ccc(COC)cc5)cc4)CCCCC3)cc2)cc1]

### Synthesis Example 2

Compound 2 represented by Chemical Formula B was obtained in the same manner as in Synthesis Example 1 except that 3-fluorobenzaldehyde (0.6 mol) was used instead of the 4-fluorobenzaldehyde.

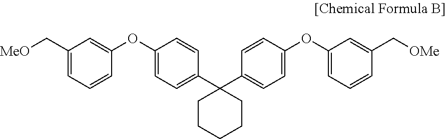 [SMILES: COCc1cccc(Oc2ccc(C3(c4ccc(Oc5cccc(COC)c5)cc4)CCCCC3)cc2)c1]

### Synthesis Example 3

Compound 3 represented by Chemical Formula C was obtained in the same manner as in Synthesis Example 1 except that 1,1-bis(4-hydroxyphenyl)cyclopentane (0.3 mol) was used instead of the 1,1-bis(4-hydroxyphenyl)cyclohexane.

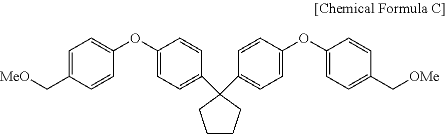 [SMILES: COCc1ccc(Oc2ccc(C3(c4ccc(Oc5ccc(COC)cc5)cc4)CCCC3)cc2)cc1]

### Synthesis Example 4

Compound 1a (95.3 g, 0.2 mol), 3-chloroperbenzoic acid (mCPBA) (86.3 g, 0.5 mol), and 200 mL of chloroform were put in a flask and stirred at ambient temperature for 4 hours. When a reaction was completed, after removing the solvent under a reduced pressure, a solid produced therein was filtered and removed, and a filtrate therefrom was purified through column chromatography method to obtain Compound 4a represented by Chemical Formula 4a.

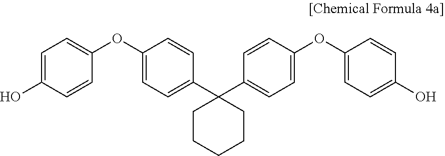 [SMILES: Oc1ccc(Oc2ccc(C3(c4ccc(Oc5ccc(O)cc5)cc4)CCCCC3)cc2)cc1]

Compound 4 represented by Chemical Formula D was obtained in the same manner as in Synthesis Example 1 except that Compound 4a (0.3 mol) was used instead of the 1,1-bis(4-hydroxyphenyl)cyclohexane.

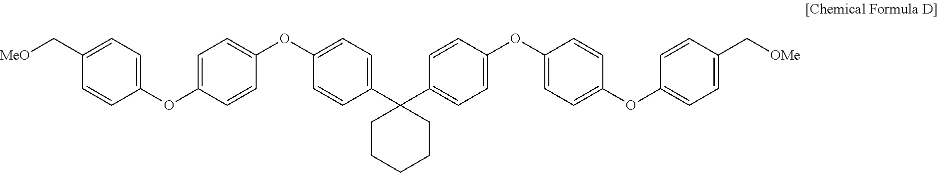 [SMILES: COCc1ccc(Oc2ccc(Oc3ccc(C4(c5ccc(Oc6ccc(Oc7ccc(COC)cc7)cc6)cc5)CCCCC4)cc3)cc2)cc1]

### Synthesis Example 5

Compound 5 represented by Chemical Formula E was obtained in the same manner as in Synthesis Example 1 except that bisphenol A (0.3 mol) was used instead of the 1,1-bis(4-hydroxyphenyl)cyclohexane.

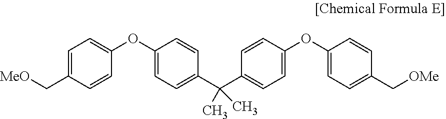 [SMILES: COCc1ccc(Oc2ccc(C(C)(C)c3ccc(Oc4ccc(COC)cc4)cc3)cc2)cc1]

### Synthesis Example 6

Compound 6 represented by Chemical Formula F was obtained in the same manner as in Synthesis Example 1 except that 9,9-bis(4-hydroxyphenyl) fluorene (0.3 mol) was used instead of the 1,1-bis(4-hydroxyphenyl)cyclohexane.

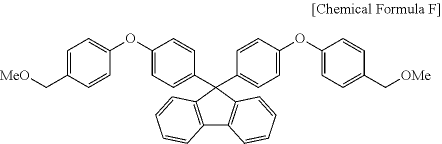 [SMILES: COCc1ccc(Oc2ccc(C3(c4ccc(Oc5ccc(COC)cc5)cc4)c4ccccc4-c4ccccc43)cc2)cc1]

### Synthesis of Polymers

### Polymerization Example 1

9,9-bis(6-hydroxy-2-naphthyl)fluorene (22.5 g, 0.05 mol), the compound 1 (25.4 g, 0.05 mol), diethyl sulfate (0.15 g), propylene glycol monomethyl ether acetate (PGMEA, 150 g) were sequentially put in a flask and then, stirred at 90° C. for 6 hours for polymerization. When a reaction was completed, the reactant was added to 40 g of distilled water and 200 g of methanol and then, vigorously stirred and allowed to stand. Subsequently, after removing a supernatant, precipitates therefrom were dissolved in 80 g of propylene glycol monomethyl ether acetate and then, stirred by using 200 g of methanol and allowed to stand. This purification process was performed two additional times, the purified polymer was dissolved in 80 g of PGMEA, and the remaining solvent was removed under a reduced pressure to obtain Polymer 1 including a structural unit represented by Chemical Formula 1-1. (Weight average molecular weight=3,000 g/mol)

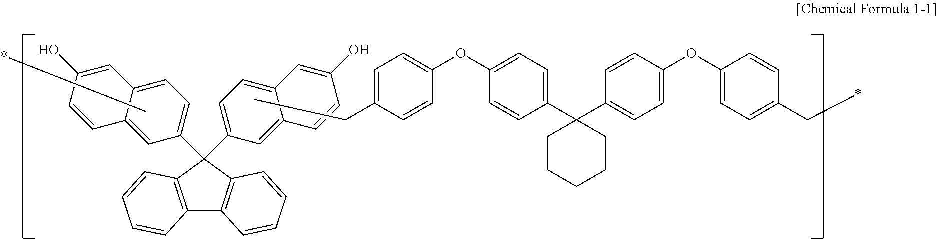

### Polymerization Example 2

Polymer 2 including a structural unit represented by Chemical Formula 1-2 was obtained in the same manner as in Polymerization Example 1 except that 0.05 mol of 1-hydroxypyrene was used instead of the 9,9-bis(6-hydroxy-2-naphthyl)fluorene. (Weight average molecular weight=3,000 g/mol)

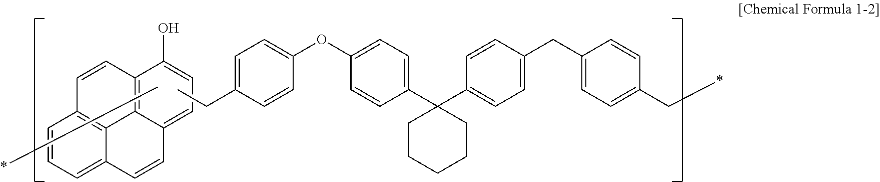

### Polymerization Example 3

Polymer 3 including a structural unit represented by Chemical Formula 1-3 was obtained in the same manner as in Polymerization Example 1 except that Compound 2 was used instead of Compound 1. (Weight average molecular weight=3,000 g/mol)

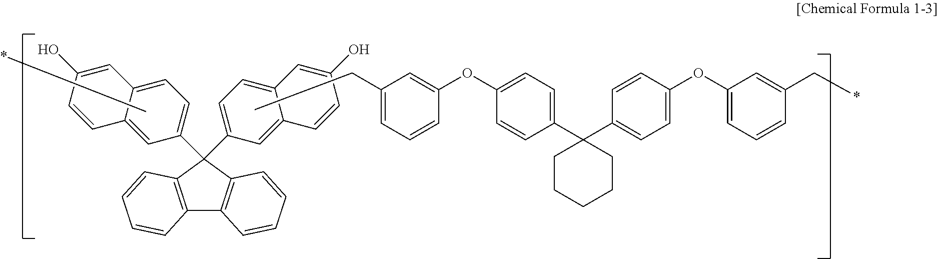

### Polymerization Example 4

Polymer 4 including a structural unit represented by Chemical Formula 1-4 was obtained in the same manner as in Polymerization Example 1 except that Compound 3 was used instead of Compound 1. (Weight average molecular weight=3,000 g/mol)

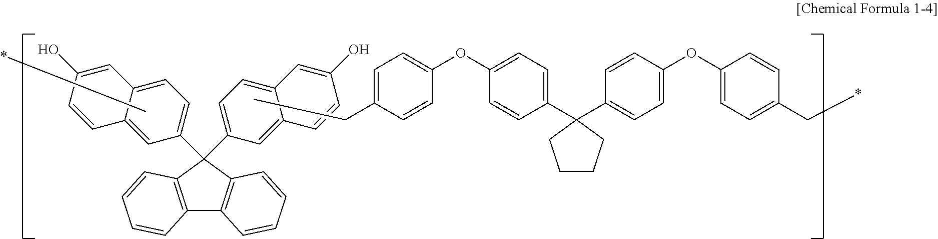

### Polymerization Example 5

Polymer 5 including a structural unit represented by Chemical Formula 1-5 was obtained in the same manner as in Polymerization Example 1 except that Compound 4 was used instead of Compound 1. (Weight average molecular weight=3,000 g/mol)

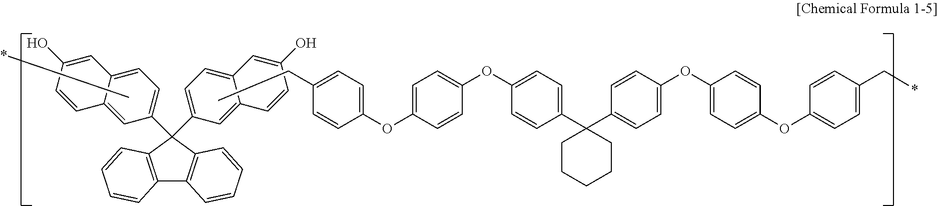

### Polymerization Example 6

Polymer 6 including a structural unit represented by Chemical Formula 1-6 was obtained in the same manner as in Polymerization Example 1 except that Compound 5 was used instead of Compound 1. (Weight average molecular weight=3,000 g/mol)

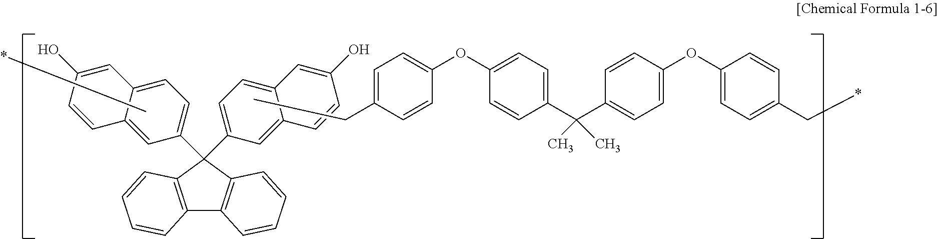

### Polymerization Example 7

Polymer 7 including a structural unit represented by Chemical Formula 1-7 was obtained in the same manner as in Polymerization Example 1 except that Compound 6 was used instead of Compound 1. (Weight average molecular weight=3,000 g/mol)

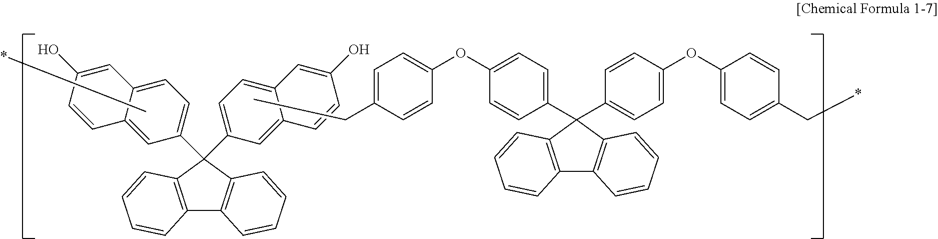

### Comparative Polymerization Example 1

28.83 g (0.2 mol) of 1-naphthol, 41.4 g (0.15 mol) of benzoperylene, and 12.08 g (0.4 mol) of p-formaldehyde were put in the 3-neck flask, and 0.57 g (0.003 mol) of p-toluene sulfonic acid monohydrate was dissolved in 163 g of PGMEA and then, stirred at 60° C. for 18 hours for polymerization. When the reaction was completed, the reactants were added to 40 g of distilled water and 400 g of methanol and then, vigorously stirred and allowed to stand. Subsequently, after removing a supernatant, precipitates therefrom were dissolved in 80 g of PGMEA and then, vigorously stirred by using 320 g of methanol and allowed to stand. This purification process was performed two more times, the purified polymer was dissolved in 80 g of PGMEA, and methanol and distilled water remaining in the solution were removed under a reduced pressure. Then, 1 L of tetrahydrofuran was added to the concentrated solution and then, slowly added dropwise to a beaker containing 1 L of hexane, while stirring, to form precipitates and thereby, obtain Comparative Polymer 1 including a structural unit represented by Chemical Formula X. (Weight average molecular weight (Mw)=4,000 g/mol, Polydispersity (PD)=1.75)

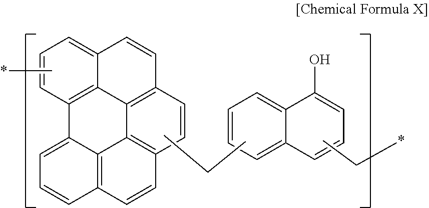

### Comparative Polymerization Example 2

Comparative Polymer 2 including a structural unit represented by Chemical Formula Y was obtained in the same manner as in Polymerization Example 1 except that 4,4′-bis(methoxymethyl)diphenyl ether was used instead of Compound 1. (Weight average molecular weight (Mw)=3,000 g/mol)

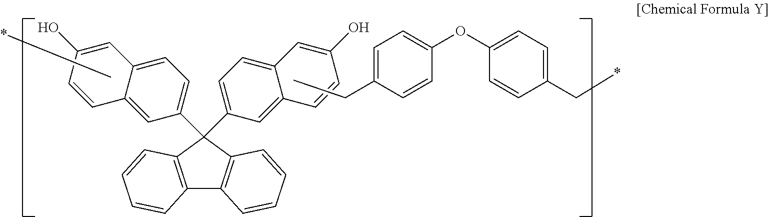

### Preparation of Hardmask Composition

### Examples 1 to 7 and Comparative Examples 1 to 2

3.5 g of each of Polymers 1 to 7 and Comparative Polymers 1 and 2 of Polymerization Examples 1 to 7 and Comparative Polymerization Examples 1 and 2 was dissolved in 10 g of a mixed solvent of PGMEA and cyclohexanone in a volume ratio of 7:3 and then, filtered with a syringe filter to prepare hardmask composition solutions.

### Evaluation 1: Evaluation of Heat Resistance

Each of the hardmask compositions according to Examples 1 to 7 and Comparative Examples 1 and 2 was coated on a silicon wafer and heat-treated on a hotplate at 150° C. for 2 minutes and then, scratched by a knife into a pellet, and a thermogravimetric (TGA) analysis was performed in the air under a condition of increasing a temperature. The results are shown in Table 1. In Table 1, T₉₅ indicates a temperature where a residual weight reached 95% of the initial weight, and T₉₀ indicates a temperature where the residual weight reached 90% of the initial weight.

TABLE 1

| | T₉₅ (° C.) | T₉₀ (° C.) |
|---|---|---|
| Example 1 | 418 | 459 |
| Example 2 | 411 | 449 |
| Example 3 | 410 | 458 |
| Example 4 | 400 | 451 |
| Example 5 | 420 | 460 |
| Example 6 | 385 | 446 |
| Example 7 | 390 | 449 |
| Comparative Example 1 | 328 | 367 |
| Comparative Example 2 | 383 | 437 |

Referring to Table 1, the hardmask layers formed of the compositions according to Examples 1 to 7 exhibited a higher thermal decomposition temperature than the hardmask layers formed of the compositions according to Comparative Examples 1 and 2. The hardmask layers of the Examples exhibited excellent heat resistance, compared with the hardmask layers of the Comparative Examples.

### Evaluation 2: Gap-Fill and Planarization Characteristics

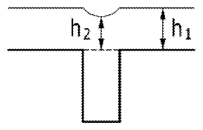

Each of the hardmask compositions of Examples 1 to 7 and Comparative Examples 1 and 2 was coated on a patterned wafer and then, heat-treated on a hot plate at 400° C. for 2 minutes to form a 2,000 Å-thick hardmask layer. The FIG. 1s a reference view exemplarily showing a step of the hardmask layers in order to explain a method of evaluating planarization characteristics.

The planarization characteristics were evaluated by using a thin film thickness meter made by K-MAC Co., Ltd. to measure a thickness at three random points on a non-patterned portion of a substrate and calculate an average thereof h1 and also, measure a thickness of a thin film at three random points on a patterned portion of the substrate and calculate an average thereof h2 and thus to calculate a step (|h1−h₂|). The smaller step (|h₁−h₂|), the better planarization characteristics.

The gap-fill characteristics were evaluated by observing the cross-section of the pattern with a scanning electron microscope (SEM) to check whether voids were generated or not, and the results are shown in Table 2.

TABLE 2

| | Planarization characteristics | | |
|---|---|---|---|
| | (h1-h2, Å) | | |
| | aspect ratio | aspect ratio | Gap-fill characteristics |
| | (1:2) | (1:10) | (with or without voids) |
| Example 1 | 52 | 120 | Voids were not present |
| Example 2 | 87 | 175 | Voids were not present |
| Example 3 | 58 | 132 | Voids were not present |
| Example 4 | 92 | 152 | Voids were not present |
| Example 5 | 89 | 168 | Voids were not present |
| Example 6 | 65 | 108 | Voids were not present |
| Example 7 | 94 | 189 | Voids were not present |
| Comparative | 132 | 321 | Voids were generated |
| Example 1 | | | |
| Comparative | 96 | 206 | Voids were not present |
| Example 2 | | | |

Referring to Table 2, the hardmask layers formed from the hardmask compositions according to Examples 1 to 7 exhibited a relatively small difference between h1 and h2, and no voids were observed in the pattern. On the other hand, the hardmask layers formed from the hardmask composition according to Comparative Examples 1 and 2 exhibited a relatively large difference between h1 and h2, and at the same time, in the case of Comparative Example 1, voids were observed within the pattern. In other words, the hardmask layers formed of the hardmask compositions of the Examples exhibited excellent planarization characteristics and also, excellent gap-fill characteristics.

By way of summation and review, there is a constant trend in a semiconductor industry to reduce a size of chips. In order to respond to this, the line width of the resist patterned in lithography technology must be tens of nanometers in size. Accordingly, a height that can withstand the line width of the resist pattern may be limited, and there are cases where the resists do not have sufficient resistance in the etching step. In order to compensate for this, an auxiliary layer, which is called a hardmask layer, may be used between a material layer to be etched and a photoresist layer. This hardmask layer serves as an interlayer that transfers a fine pattern of the photoresist through selective etching, and thus the hardmask layer is required to have etch resistance and crosslinking characteristics to withstand the etching process required for pattern transfer.

Some hardmask layers may be formed in a chemical or physical deposition method and may have low economic efficiency due to a large-scale equipment and a high process cost. Accordingly, a spin-coating technique for forming a hardmask layer has recently been developed. The spin-coating technique may be an easier process to conduct than some other methods, and a hardmask layer formed therefrom may exhibit excellent gap-fill characteristics and planarization characteristics. However, in the hardmask layer formed using the spin-coating technique, the required etch resistance may be somewhat lowered. Accordingly, a hardmask composition may be applied using the spin-coating technique to secure equivalent etch resistance to that of the hardmask layer formed in the chemical or physical deposit method.

Accordingly, in order to improve the etch resistance of a hardmask layer, research on maximizing a carbon content of the hardmask composition is being made. However, as a carbon content of a polymer included in the hardmask composition is maximized, solubility of the compound in a solvent may be reduced. Therefore, a carbon content of the polymer included in the hardmask composition should be maximized to improve the etch resistance of the hardmask layer formed therefrom, while the polymer must be well soluble in the solvent.

The hardmask composition according to some embodiments may include a polymer including an aromatic hydrocarbon group or a heteroaromatic group, thereby increasing a carbon content in the polymer and ensuring etch resistance of the hardmask layer formed therefrom. At the same time, by including a moiety with high flexibility in the polymer, a solubility of the polymer in a solvent is increased, so that the gap-fill and planarization characteristics of the hardmask layer formed from the composition can be improved and heat resistance may be improved.

One or more embodiments may provide a hardmask composition that can be effectively applied to a hardmask layer.

The hardmask composition according to some embodiments may have excellent solubility in solvents and may be effectively applied to a hardmask layer.

A hardmask layer formed from a hardmask composition according to some embodiments may help secure excellent heat resistance and simultaneously gap-fill characteristics and planarization characteristics at the same time.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a polymer including a structural unit represented by Chemical Formula 1; and
a solvent: 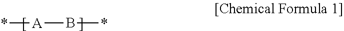
wherein, in Chemical Formula 1,
A is a substituted or unsubstituted aromatic group, a substituted or unsubstituted heteroaromatic group, a group in which two or more substituted or unsubstituted aromatic groups or substituted or unsubstituted heteroaromatic groups are linked by a single bond or —CR^{x}R^{y}—, in which R^{x} and R^{y} are each independently a substituted or unsubstituted aromatic group or a substituted or unsubstituted heteroaromatic group, R^{x} and R^{y} being separate or linked to form a fused ring, or a combination thereof,
B is a group represented by Chemical Formula 2, and
* is a linking point: 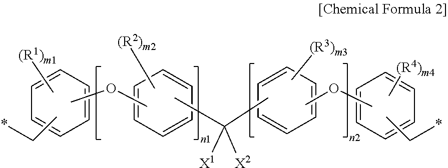
wherein, in Chemical Formula 2,
X¹ and X² are each independently a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C1 to C20 saturated or unsaturated heteroaliphatic hydrocarbon group, a substituted or unsubstituted C2 to C20 saturated or unsaturated heteroalicyclic hydrocarbon group, a substituted or unsubstituted C6 to C30 aromatic group, a substituted or unsubstituted C6 to C30 heteroaromatic group, or a combination thereof, X¹ and X² being separate or being linked to each other to form a substituted or unsubstituted C3 to C30 hydrocarbon ring group,
R¹ to R⁴ are each independently deuterium, a hydroxy group, a halogen atom, —NR^{a}R^{b}, in which R^{a} and R^{b} are each independently hydrogen or a substituted or unsubstituted C1 to C10 alkyl group, a substituted or unsubstituted C1 to C20 alkoxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C3 to C20 cycloalkenyl group, a substituted or unsubstituted C3 to C20 cycloalkynyl group, a substituted or unsubstituted C3 to C20 hetero cycloalkyl group, a substituted or unsubstituted C6 to C20 aryl group, a substituted or unsubstituted C6 to C20 heteroaryl group, or a combination thereof,
m1 to m4 are each independently an integer of 0 to 4, and
n1 and n2 are each independently an integer of 1 to 4.

2. The hardmask composition as claimed in claim 1, wherein A is a substituted or unsubstituted C6 to C20 aromatic group, a moiety in which two or more substituted or unsubstituted C6 to C20 aromatic rings are linked by a single bond or —CR^{x}R^{y}—, in which R^{x} and R^{y} are each independently a substituted or unsubstituted C6 to C10 aromatic ring, R^{x} and R^{y} being separate or linked to form a fused ring, or a combination thereof.

3. The hardmask composition as claimed in claim 1, wherein:
A is a substituted or unsubstituted group of a moiety of Group 1 or a moiety of Group 2, 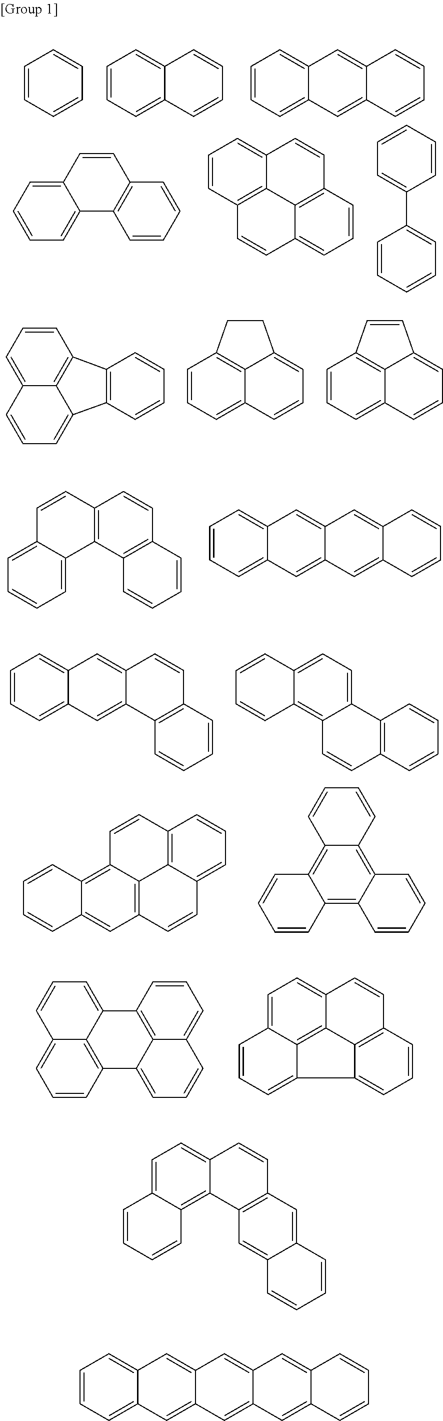 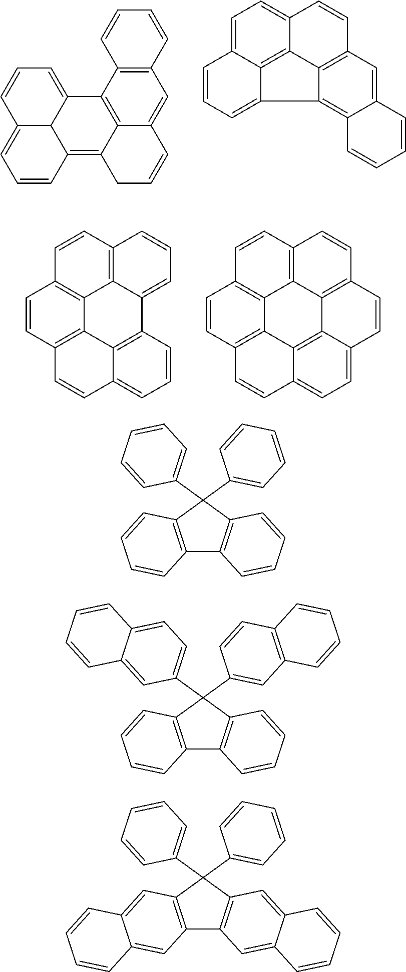 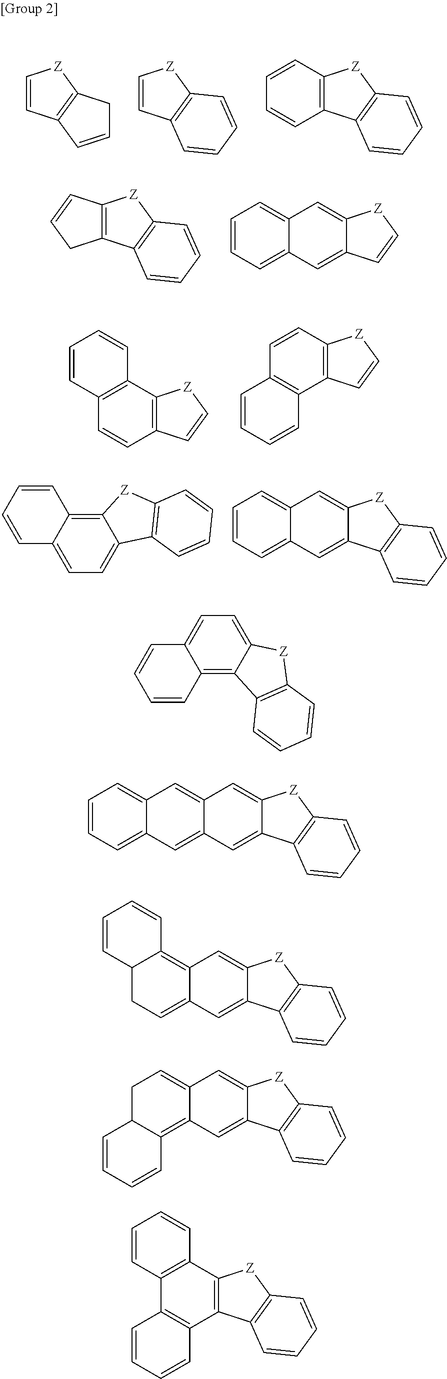 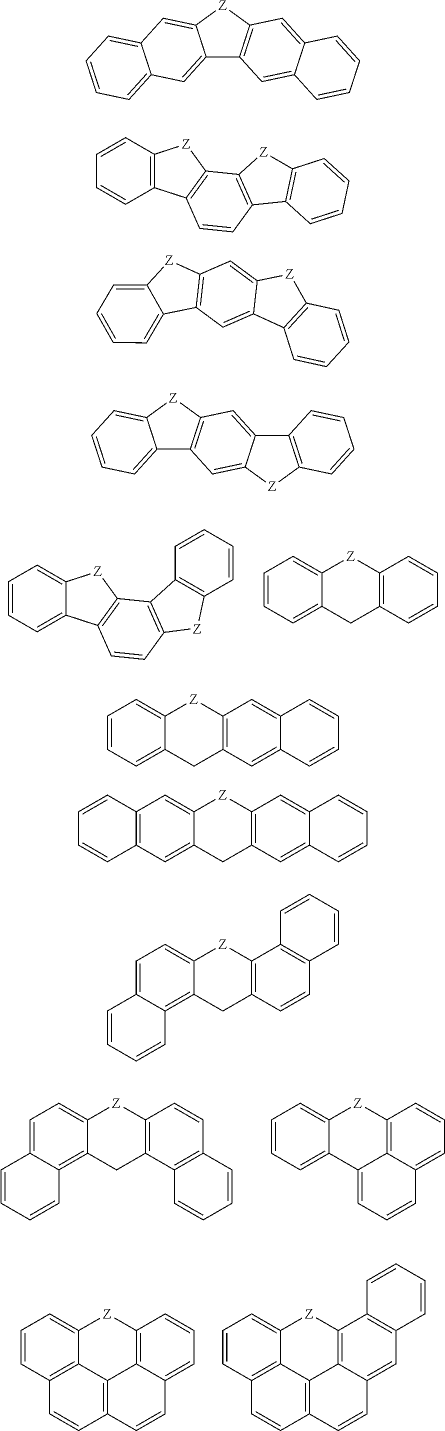 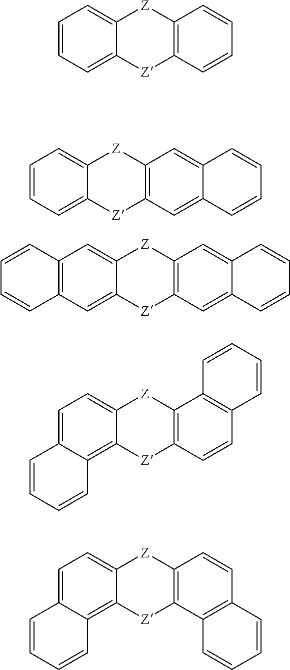
in Group 2, Z and Z′ are each independently —O—, —S—, —P—, or —NR^{c}—, in which R^{c} is hydrogen, deuterium, or a substituted or unsubstituted C1 to C5 alkyl group.

4. The hardmask composition as claimed in claim 1, wherein, in Chemical Formula 2,
X¹ and X² are each independently a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C30 aromatic ring group, or a combination thereof, and
X¹ and X² are linked to form a substituted or unsubstituted C3 to C20 hydrocarbon cyclic group.

5. The hardmask composition as claimed in claim 1, wherein, in Chemical Formula 2,
X¹ and X² are each independently a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C20 aryl group, or a combination thereof, and
X¹ and X² are linked to form a substituted or unsubstituted C3 to C20 hydrocarbon cyclic group.

6. The hardmask composition as claimed in claim 1, wherein, in Chemical Formula 2,
R¹ to R⁴ are each independently deuterium, a hydroxy group, a halogen atom, a substituted or unsubstituted C1 to C20 alkoxy group, a substituted or unsubstituted C1 to C10 alkyl group, a substituted or unsubstituted C6 to C20 aryl group, or a combination thereof, and
m1 to m4 are each independently an integer of 0 to 2.

7. The hardmask composition as claimed in claim 1, wherein, in Chemical Formula 2,
X¹ and X² are each independently a substituted or unsubstituted C1 to C20 alkyl group, a substituted or unsubstituted C6 to C20 aryl group, wherein X¹ and X² are linked to form a substituted or unsubstituted C3 to C20 hydrocarbon cyclic group, or a combination thereof,
m1 to m4 are each 0, and
n1 and n2 are each independently 1 or 2.

8. The hardmask composition as claimed in claim 1, wherein:
Chemical Formula 2 is represented by one of Chemical Formula 2-1 to Chemical Formula 2-5: 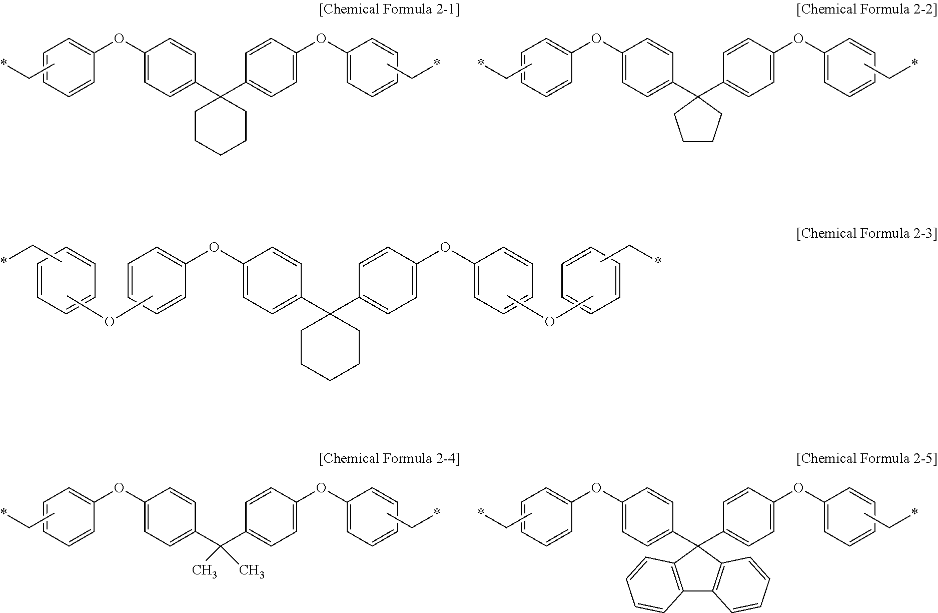
in Chemical Formula 2-1 to Chemical Formula 2-5, * is a linking point.

9. The hardmask composition as claimed in claim 1, wherein:
Chemical Formula 1 is represented by one of Chemical Formula 1-1 to Chemical Formula 1-7, 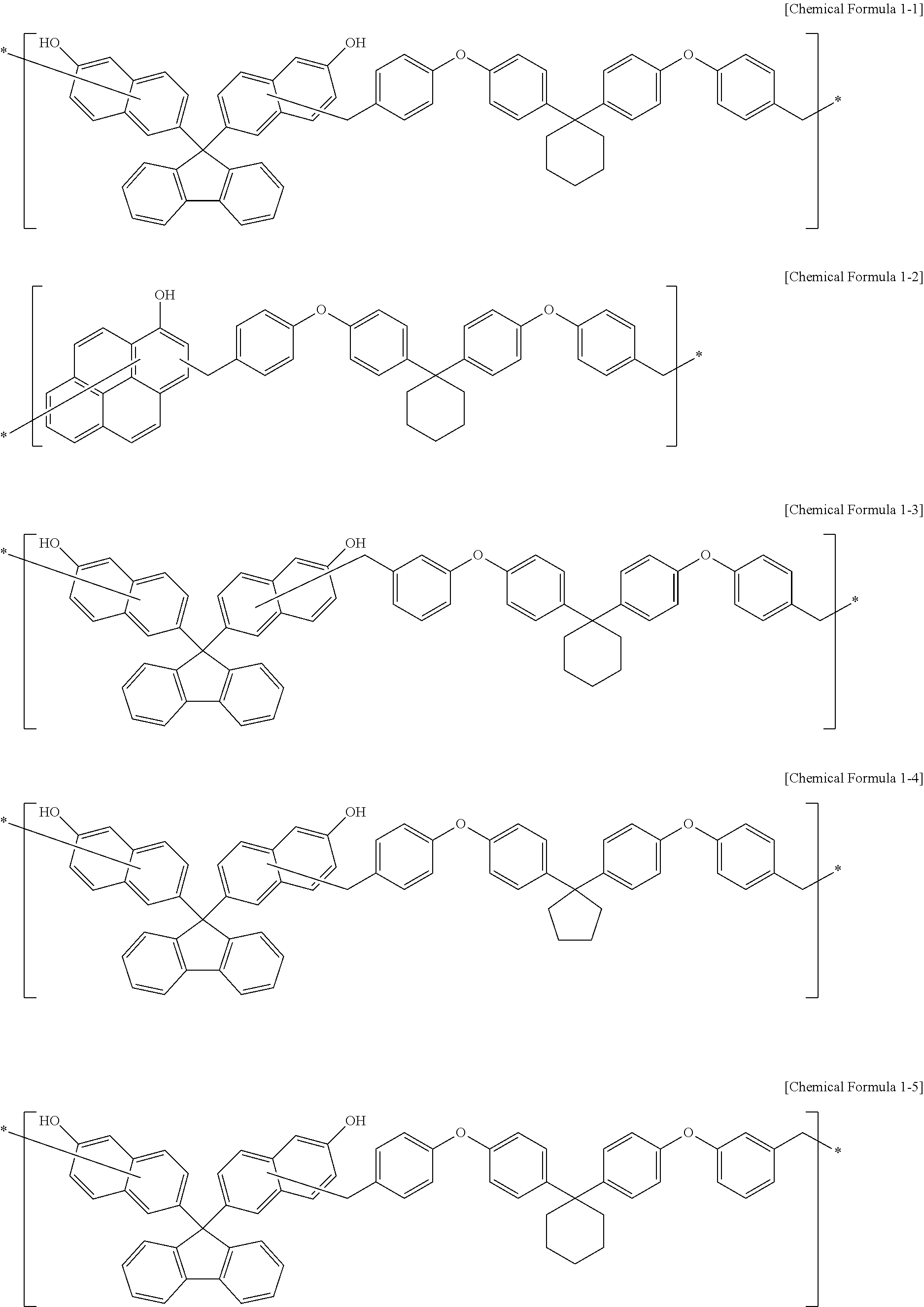 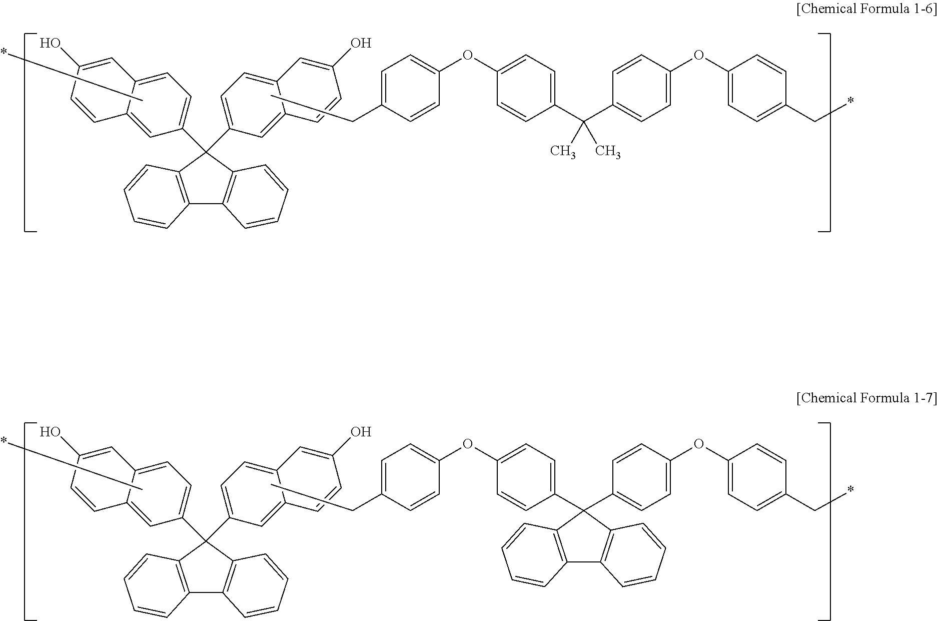
in Chemical Formula 1-1 to Chemical Formula 1-7, * is a linking point.

10. The hardmask composition as claimed in claim 1, wherein the polymer has a weight average molecular weight of about 1,000 g/mol to about 200,000 g/mol.

11. The hardmask composition as claimed in claim 1, wherein the polymer is included in an amount of about 0.1 wt % to about 30 wt %, based on a total weight of the hardmask composition.

12. The hardmask composition as claimed in claim 1, wherein the solvent includes propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

13. A hardmask layer comprising a cured product of the hardmask composition as claimed in claim 1.

14. A method of forming patterns, the method comprising:
providing a material layer on a substrate;
applying the hardmask composition as claimed in claim 1 to the material layer;
heat-treating the hardmask composition to form a hardmask layer;
forming a photoresist layer on the hardmask layer;
exposing and developing the photoresist layer to form a photoresist pattern;
selectively removing the hardmask layer using the photoresist pattern to expose a portion of the material layer; and
etching an exposed part of the material layer.

15. The method as claimed in claim 14, wherein forming the hardmask layer includes heat-treating at about 100° C. to about 1,000° C.
